(19) United States
(12) Patent Application Publication
(10) Pub. No.: US 2026/0063685 A1
(43) Pub. Date: Mar. 5, 2026

(54) POWER DETECTION CIRCUIT, RADIO FREQUENCY INTEGRATED CIRCUIT, AND WIRELESS COMMUNICATION DEVICE

(71) Applicant: Fujikura Ltd., Tokyo (JP)

(72) Inventors: Ken Sakuma, Sakura-shi (JP); Chihiro Kamidaki, Sakura-shi (JP)

(73) Assignee: Fujikura Ltd., Tokyo (JP)

(21) Appl. No.: 19/314,425

(22) Filed: Aug. 29, 2025

(30) Foreign Application Priority Data
Sep. 2, 2024 (JP) 2024-150597

(51) Int. Cl. G01R 19/165; H03M 1/12

(52) U.S. Cl. CPC G01R 19/16528; G01R 19/16552; G01R 19/16557; H03M 1/12

(57) ABSTRACT

A power detection circuit includes a power detector that detects output power of a power amplifier and outputs in two ways of a voltage output and a current output as a detection result, and a voltage comparison circuit that compares the voltage output of the power detector with a predetermined reference voltage and outputs a power detection signal that is at a level "H" in a case where the voltage output is higher than the reference voltage and is at a level "L" in a case where the voltage output is lower than the reference voltage.

### CROSS-REFERENCE TO RELATED APPLICATION

Priority is claimed on Japanese Patent Application No. 2024-150597 filed September 2, 2024, the content of which is incorporated herein by reference.

### BACKGROUND OF THE INVENTION

### FIELD OF THE INVENTION

The present invention relates to a power detection circuit, a radio frequency integrated circuit, and a wireless communication device.

### DESCRIPTION OF RELATED ART

A wireless communication device may include a power detector (PD) on a path from a power amplifier (PA) to an antenna. In such a wireless communication device, power of a radio signal transmitted from the antenna is stabilized using a detection result of the power detector. Such a wireless communication device is disclosed in United States Patent No. 4983981, United States Patent No. 11777544, and United States Patent Application, Publication No. 2023/0280395 below.

For example, United States Patent No. 4983981 discloses a wireless communication device that stabilizes the level of radiated RF energy transmitted from an antenna by adjusting an amplification gain of a power amplifier based on a comparison result between a detection result of a power detector and a predetermined reference value. United States Patent No. 11777544 discloses a wireless communication device that stabilizes power of a radio signal transmitted from an antenna by compensating for an amplification distortion originating from a characteristic of a power amplifier by performing digital pre-distortion (DPD) processing during baseband signal processing based on a detection result of a power detector.

### SUMMARY OF THE INVENTION

In the wireless communication device, it may be desired to achieve both early detection of an abnormality in output power of the power amplifier and accurate and precise measurement of the output power. In detecting the abnormality in the output power, it may be desired to flexibly handle various error detection conditions. For example, in a phased array antenna module, changing a reference for determining the abnormality in the output power of the power amplifier in accordance with setting content of a beam table in which an amplification gain setting value of the power amplifier provided in accordance with each of a plurality of antenna elements is set.

In order to detect the abnormality in the output power of the power amplifier early, it is preferable to compare the detection result of the power detector with a predetermined reference voltage. However, a problem arises in that the output power cannot be quantitatively evaluated through only the comparison with respect to the predetermined reference voltage. In addition, as in the wireless communication device disclosed in United States Patent No. 4983981, in the configuration of using the comparison result with respect to the reference voltage in only a feedback control of the amplification gain of the power amplifier, a problem arises in that various error detection conditions cannot be flexibly handled.

In order to accurately and precisely measure the output power of the power amplifier, it is preferable to convert the detection result of the power detector into a digital value by inputting the detection result into an analog-to-digital converter (ADC). However, converting the detection result of the power detector into a digital value requires a certain amount of time. Thus, there is a problem of low real-time performance.

The present invention is conceived in view of the above circumstances, and an object thereof is to provide a power detection circuit, a radio frequency integrated circuit, and a wireless communication device capable of achieving both of early detection of an abnormality in output power of a power amplifier and accurate and precise measurement of the output power.

In order to address the above issue, a power detection circuit (70) according to one aspect of the present invention includes a power detector (70a) configured to detect output power of a power amplifier (65) and output a detection result in two ways of a voltage output (VO) and a current output (IO), and includes a voltage comparison circuit (70b) configured to compare the voltage output of the power detector with a predetermined reference voltage (Vr) and output a power detection signal (DT) that is at a first level when the voltage output is higher than the reference voltage and is at a second level when the voltage output is lower than the reference voltage.

In the power detection circuit according to one aspect of the present invention, the detection result of the output power of the power amplifier is output in two ways of the voltage output and the current output. The voltage output, which is one of the two ways, is compared with the predetermined reference voltage, and the power detection signal (a digital signal) where the level changes in accordance with a comparison result is output. In the power detection circuit according to one aspect of the present invention, the power detection signal indicating the comparison result between the voltage output and the reference voltage and the current output indicating the detection result of the output power of the power amplifier are output. Accordingly, both of early detection of the abnormality in the output power of the power amplifier and accurate and precise measurement of the output power can be achieved.

A radio frequency integrated circuit (10) according to a first aspect of the present invention includes the power detection circuit (70) of one aspect configured to detect the output power of the power amplifier, a circuit portion (12) that includes the power amplifier (65) and a variable gain amplifier (63) and is configured to amplify a radio frequency signal supplied to an antenna element (21), and a first abnormality detection circuit (16) configured to detect presence or absence of an abnormality in the radio frequency signal based on a gain setting value defining a gain setting of the circuit portion and on the power detection signal output from the voltage comparison circuit of the power detection circuit.

According to a radio frequency integrated circuit according to a second aspect of the present invention, in the radio frequency integrated circuit according to the first aspect of the present invention, the first abnormality detection circuit may output a first abnormality signal (AL) in a case where the gain setting value is higher than a first setting reference value and the power detection signal is at the second level, and output a second abnormality signal (AH) in a case where the gain setting value is lower than a second setting reference value lower than the first setting reference value and the power detection signal is at the first level.

According to a radio frequency integrated circuit according to a third aspect of the present invention, in the radio frequency integrated circuit according to the second aspect of the present invention, the first abnormality detection circuit might not output the first abnormality signal and the second abnormality signal when the gain setting value is lower than the first setting reference value and higher than the second setting reference value.

According to a radio frequency integrated circuit according to a fourth aspect of the present invention, in the radio frequency integrated circuit according to the second aspect of the present invention, the reference voltage may be set such that a level of the power detection signal is switched when the gain setting value is a value between the first setting reference value and the second setting reference value.

A radio frequency integrated circuit according to a fifth aspect of the present invention includes a circuit portion (12) including a power amplifier (65) that amplifies a radio frequency signal supplied to an antenna element (21), the power detection circuit (70) of one aspect configured to detect the output power of the power amplifier, a conversion circuit (71) configured to convert the current output of the power detector into a digital value, and a second abnormality detection circuit (6c) configured to detect presence or absence of an abnormality in the radio frequency signal based on the digital value and a predetermined comparative reference value (Qr).

According to a radio frequency integrated circuit according to a sixth aspect of the present invention, in the radio frequency integrated circuit according to the fifth aspect of the present invention, the comparative reference value may be set to a value higher than the digital value converted by the conversion circuit when a gain setting value defining a gain setting of the circuit portion is a maximum value, or a value lower than the digital value converted by the conversion circuit when the gain setting value is a minimum value.

According to a radio frequency integrated circuit according to a seventh aspect of the present invention, the radio frequency integrated circuit according to the fifth aspect of the present invention may further include a storage portion (6a) configured to store the digital value converted by the conversion circuit, in which the second abnormality detection circuit detects the presence or absence of the abnormality in the radio frequency signal based on the digital value stored in the storage portion and the comparative reference value.

A wireless communication device according to a first aspect of the present invention includes the radio frequency integrated circuit (10) according to any one of the first to fourth aspects, and a controller (50) configured to acquire a detection result of the first abnormality detection circuit.

A wireless communication device according to a second aspect of the present invention includes the radio frequency integrated circuit (10) according to any one of the fifth to seventh aspects, and a controller (50) configured to acquire a detection result of the second abnormality detection circuit.

According to the present invention, an effect of achieving both of early detection of the abnormality in the output power of the power amplifier, and accurate and precise measurement of the output power can be obtained.

### BRIEF DESCRIPTION OF THE DRAWINGS

FIG. 1 is a system configuration diagram showing a configuration of a wireless communication device according to one embodiment of the present invention.

FIG. 2 is a block diagram showing a main configuration of a beamformer integrated circuit according to one embodiment of the present invention.

FIG. 3 is a block diagram showing a configuration of a power detection circuit provided in the wireless communication device according to one embodiment of the present invention.

FIG. 4 is a diagram showing a connection relationship between a digital circuit portion and an analog circuit portion provided in an RF front end of the beamformer integrated circuit according to one embodiment of the present invention.

FIG. 5 is a diagram showing a configuration of a first abnormality detection system that detects an abnormality in output power using a power detection signal output from the power detection circuit according to one embodiment of the present invention.

FIG. 6 is a diagram showing a configuration of a second abnormality detection system that detects an abnormality in the output power using a current output supplied from the power detection circuit according to one embodiment of the present invention.

### DETAILED DESCRIPTION OF THE INVENTION

Hereinafter, a power detection circuit, a radio frequency integrated circuit, and a wireless communication device according to an embodiment of the present invention will be described in detail with reference to the drawings.

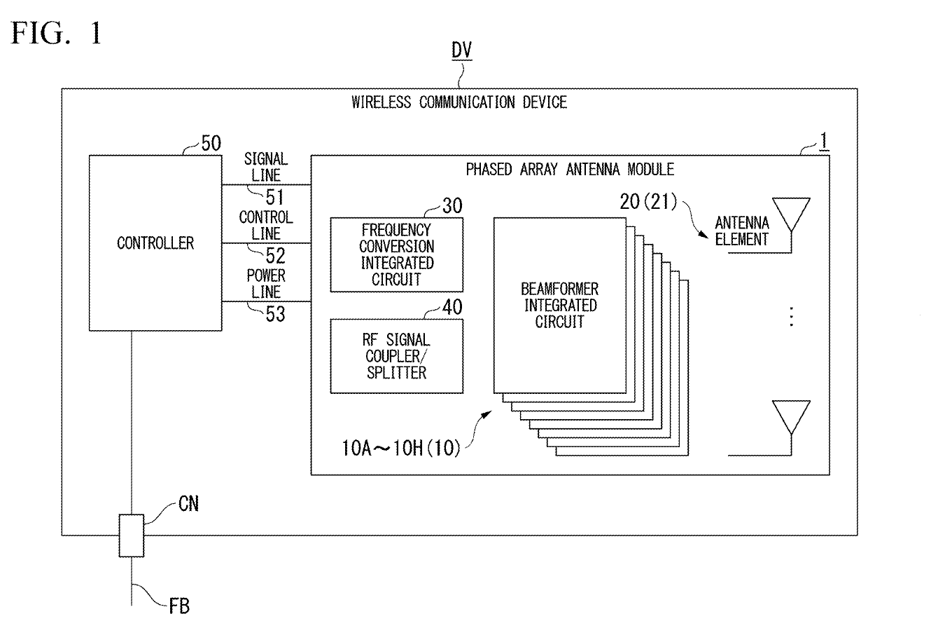

FIG. 1 is a system configuration diagram showing a configuration of the wireless communication device according to one embodiment of the present invention.

As shown in FIG. 1, a wireless communication device DV of the present embodiment includes a phased array antenna module 1 and a controller 50. The wireless communication device DV can perform beamforming in which a beam pattern can be freely changed, for example, using a millimeter wave band.

The phased array antenna module 1 includes, for example, a plurality of integrated circuits (IC) mounted on one surface of a board such as a printed circuit board in the related art, and an antenna array fabricated on the other surface of the board. The plurality of integrated circuits and the antenna array that constitute the phased array antenna module 1 are formed by using a material in the related art and by using a method in the related art. An electrical connection structure between the plurality of integrated circuits and an electrical connection structure between the integrated circuit and the antenna array are not particularly limited. A connection structure in the related art is employed as the electrical connection structure.

The controller 50 communicates with, for example, an upper-level device (not shown) installed in a base portion of a pole or a tower, or in a telecommunications facility building, through an optical fiber FB, and communicates with a facing wireless communication device such as a mobile terminal, a fixed wireless access network facility, or a base station facility using the phased array antenna module 1. The controller 50 includes an optical transceiver (not shown) or a pluggable type optical transceiver provided with an optical connector (not shown). The optical fiber FB is connected to the optical transceiver of the controller 50 via an optical connector CN installed in a housing of the wireless communication device DV.

### <Phased Array Antenna Module>

As shown in FIG. 1, the phased array antenna module 1 includes eight beamformer integrated circuits 10A, 10B, 10C, 10D, 10E, 10F, 10G, and 10H (hereinafter, referred to as the beamformer integrated circuits 10A to 10H), an antenna array 20, a frequency conversion integrated circuit 30, and an RF signal coupler/splitter 40.

The phased array antenna module 1 is connected to the controller 50 through a signal line 51, a control line 52, and a power line 53. An RF signal having a signal frequency of an intermediate frequency (IF) is transmitted and received between the controller 50 and the phased array antenna module 1 through the signal line 51. A control-related communication message is transmitted and received between the controller 50 and the phased array antenna module 1 through the control line 52. Power is supplied from the controller 50 to the phased array antenna module 1 through the power line 53.

The beamformer integrated circuits 10A to 10H are integrated circuits that control a beam pattern of the antenna array 20. A plurality of antenna elements 21 constituting the antenna array 20 are connected to each of the beamformer integrated circuits 10A to 10H. For example, eight antenna elements 21 for horizontal polarization and eight antenna elements 21 for vertical polarization are connected to each of the beamformer integrated circuits 10A to 10H. That is, the antenna array 20 is configured with total 128 antenna elements 21 including 64 antenna elements 21 for the horizontal polarization and 64 antenna elements 21 for the vertical polarization. Details of the beamformer integrated circuits 10A to 10H will be described later.

The frequency conversion integrated circuit 30 is an integrated circuit that performs frequency conversion between the RF signal having the IF signal frequency and an RF signal having a frequency transmitted and received by the beamformer integrated circuits 10A to 10H and the antenna array 20.

The RF signal coupler/splitter 40 distributes the RF signal output from the frequency conversion integrated circuit 30 to each of the beamformer integrated circuits 10A to 10H. In addition, the RF signal coupler/splitter 40 couples the RF signals received by each of the beamformer integrated circuits 10A to 10H and inputs the coupled RF signals into the frequency conversion integrated circuit 30.

### <Beamformer Integrated Circuit>

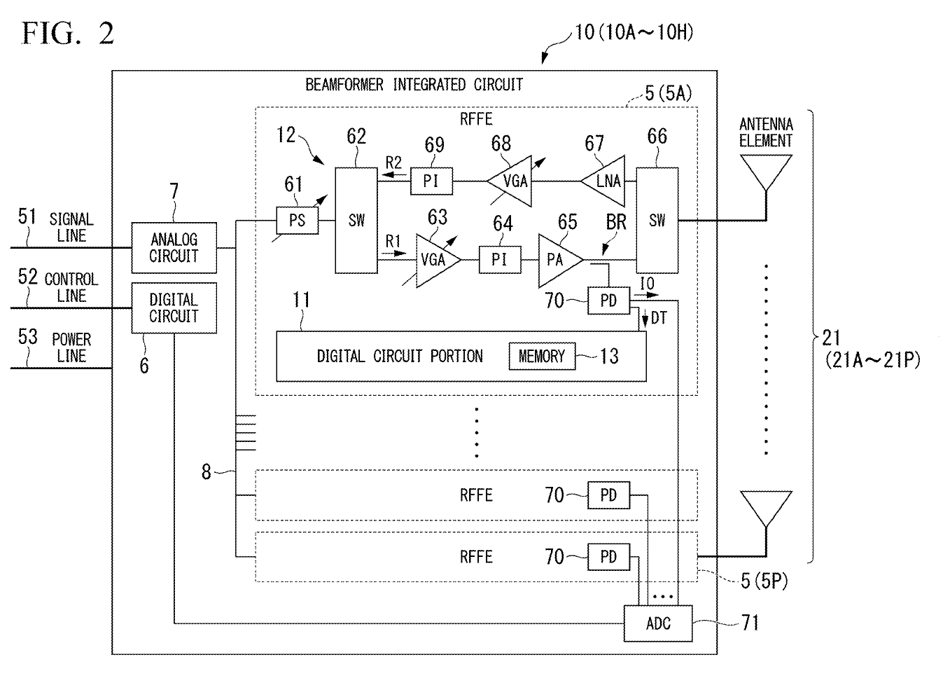

FIG. 2 is a block diagram showing a main configuration of the beamformer integrated circuit according to one embodiment of the present invention. The eight beamformer integrated circuits 10A to 10H have the same configuration.

Thus, one of the beamformer integrated circuits 10A to 10H, that is, a beamformer integrated circuit 10, may be explained in the following description. Explanations of the other seven beamformer integrated circuits may be omitted in the following description.

The beamformer integrated circuit 10 (the radio frequency integrated circuit) includes 16 RF front ends (RFFEs) 5A to 5P, a digital circuit 6, an analog circuit 7, an RF signal coupler/splitter 8, and an analog-to-digital converter (ADC) 71 (a conversion circuit). The 16 RF front ends 5A to 5P have the same configuration as each other. Thus, one of the 16 RF front ends 5A to 5P, that is, an RF front end 5, may be explained in the following description. Explanations of the other 15 RF front ends may be omitted in the following description.

In the one beamformer integrated circuit 10 shown in FIG. 2, each of the 16 RF front ends 5A to 5P is connected to respective one of 16 antenna elements 21A to 21P such that one antenna element 21 corresponds to one RF front end 5 on a one-to-one basis. Among the 16 RF front ends 5A to 5P and the 16 antenna elements 21A to 21P, 8 RF front ends (for example, the RF front ends 5A to 5H) and 8 antenna elements (for example, the antenna elements 21A to 21H) are for the horizontal polarization, and the remaining 8 RF front ends (for example, the RF front ends 5I to 5P) and the remaining 8 antenna elements (for example, the antenna elements 21I to 21P) are for the vertical polarization.

The 16 antenna elements 21A to 21P have the same configuration or similar configurations to each other. Thus, one of the 16 antenna elements 21A to 21P, that is, the antenna element 21 may be explained in the following description. Explanations of the other 15 antenna elements may be omitted. The antenna elements 21A to 21P may have the same configuration as each other. In the configurations of each of the antenna elements 21A to 21P, the configuration of the antenna element for the horizontal polarization and the configuration of the antenna element for the vertical polarization may be slightly different from each other.

In one beamformer integrated circuit 10, each of the 16 RF front ends 5A to 5P is connected to respective one of the 16 antenna elements 21A to 21P on a one-to-one basis. Thus, in the whole phased array antenna module 1 including the eight beamformer integrated circuits 10A to 10H, each of the 128 antenna elements 21 constituting the antenna array 20 is connected to respective one of the 16 RF front ends 5A to 5P in each of the eight beamformer integrated circuits 10A to 10H.

The 128 antenna elements 21 constituting the antenna array 20 are divided into the 64 antenna elements 21 that transmit and receive radio waves of the horizontal polarization, and the 64 antenna elements 21 that transmit and receive radio waves of the vertical polarization. The eight beamformer integrated circuits 10A to 10H control transmission and reception of the radio waves of the horizontal polarization in the 64 antenna elements 21, and control transmission and reception of the radio waves of the vertical polarization in the 64 antenna elements 21. For each of the radio waves of the horizontal polarization and the radio waves of the vertical polarization, the beamformer integrated circuits 10A to 10H set a phase and intensities of each of the 64 antenna elements 21 such that a direction of a combined radio wave transmitted or received from the 64 antenna elements 21 is set to a predetermined direction.

As shown in FIG. 2, the RF front end 5 includes a digital circuit portion 11 and an analog circuit portion 12 (a circuit portion). The digital circuit portion 11 transmits and receives the control-related communication message to and from the controller 50 through the control line 52 shown in FIG. 1. The digital circuit portion 11 controls the RF front end 5 based on the communication message transmitted from the controller 50.

In the present embodiment, the control-related communication message is transmitted and received through parallel communication between the phased array antenna module 1 and the controller 50. That is, the digital circuit portion 11 transmits and receives the control-related communication message through parallel communication with respect to the controller 50. Communication performed between the phased array antenna module 1 and the controller 50 is not limited to the parallel communication. Serial communication such as serial peripheral interface (SPI), inter-integrated circuit (I2C), or the like may be adopted.

The digital circuit portion 11 is connected to the digital circuit 6 through wiring in the beamformer integrated circuit 10. The digital circuit 6 relays communication performed between the digital circuit portion 11 and the controller 50. Alternatively, the digital circuit 6 communicates with the digital circuit portion 11 based on content of the communication message transmitted from the controller 50.

One communication transaction transmitted from the controller 50 to the phased array antenna module 1 includes additional information, a command, and data. The communication transaction has a fixed bit length. The command is a register address in a case where an instruction to perform writing into the register or to perform reading from the register is provided. Alternatively, the command is a numerical value indicating an operation instruction for the beamformer integrated circuit 10 or the RF front end 5. The command and the data have fixed lengths. In the present embodiment, the command is 8 bits, and the data is 16 bits.

The digital circuit portion 11 includes a memory 13 that is a storage area for storing a beam table used for beamforming. The beam table is a look-up table storing a plurality of combinations of a phase shift amount setting value and intensity setting value set in accordance with the beam pattern of the antenna array 20 to be controlled. In the present embodiment, a beam table in which 2048 combinations of the phase shift amount setting value and the intensity setting value are defined (a beam table having 2048 items) is stored in the memory 13.

The memory 13 is implemented using, for example, a static random access memory (SRAM). While the memory 13 is preferably implemented using an SRAM, the memory 13 may be implemented using a register or may be implemented using a dynamic random access memory (DRAM), a flash memory, or a read only memory (ROM).

The analog circuit portion 12 is a circuit that outputs an RF signal to the antenna element 21 connected to the RF front end 5 or receives an RF signal output from the antenna element 21. Under control of the digital circuit portion 11, the analog circuit portion 12 adjusts a phase and intensity of the RF signal transmitted and received by the antenna element 21 connected to the RF front end 5.

The analog circuit portion 12 is connected to the analog circuit 7 through the RF signal coupler/splitter 8. The RF signal coupler/splitter 8 distributes an RF signal output from the analog circuit 7 to the analog circuit portions 12 provided in each of the RF front ends 5A to 5P. In addition, the RF signal coupler/splitter 8 couples the RF signals output from the analog circuit portions 12 provided in each of the RF front ends 5A to 5P and outputs the coupled RF signal to the analog circuit 7.

As shown in FIG. 2, the analog circuit portion 12 includes a phase shifter (PS) 61, a path selection switch (SW) 62, a variable gain amplifier (VGA) 63, a phase inverter (PI) 64, a power amp (PA) 65, a path selection switch (SW) 66, a low-noise amp (LNA) 67, a variable gain amplifier (VGA) 68, a phase inverter (PI) 69, and a power detection circuit (PD) 70.

The variable gain amplifier 63, the phase inverter 64, and the power amplifier 65 are provided on a transmission path R1, and the low-noise amplifier 67, the variable gain amplifier 68, and the phase inverter 69 are provided on a reception path R2. The transmission path R1 is a path through which the RF signal (a radio frequency signal) output to the antenna element 21 passes, and the reception path R2 is a path through which the RF signal (a radio frequency signal) input from the antenna element 21 passes. The path selection switches 62 and 66 switch to connect to the transmission path R1 or connect to the reception path R2 between the phase shifter 61 and the antenna element 21 at a predetermined time interval. Accordingly, the phased array antenna module 1 can transmit and receive a radio frequency signal as a time-division multiplexing system.

The phase shifter 61 adjusts a phase shift amount of the RF signal passing through the transmission path R1 or the RF signal passing through the reception path R2 in accordance with the phase shift amount setting value of the beam table read from the memory 13 of the digital circuit portion 11. That is, the phase shifter 61 is provided in common to the transmission path R1 and the reception path R2. A configuration may be adopted in which the phase shifter 61 common to the transmission path R1 and the reception path R2 is omitted and phase shifters are individually provided on the transmission path R1 and the reception path R2.

The variable gain amplifier 63 amplifies the RF signal passing through the transmission path R1 in accordance with the intensity setting value of the beam table read from the memory 13. The phase inverter 64 inverts a phase of the RF signal passing through the transmission path R1 in accordance with the phase shift amount setting value of the beam table read from the memory 13. The power amplifier 65 (a power amplifier) amplifies the RF signal passing through the transmission path R1 at a predetermined gain setting. By adjusting the phase shift amount and the strength of the RF signal passing through the transmission path R1, the beam pattern of the radio wave transmitted from the phased array antenna module 1 can be changed.

The low-noise amplifier 67 amplifies the RF signal output from the path selection switch 66 at a predetermined gain setting. The variable gain amplifier 68 amplifies the RF signal passing through the reception path R2 in accordance with the intensity setting value of the beam table read from the memory 13. The phase inverter 69 inverts a phase of the RF signal passing through the reception path R2 in accordance with the phase shift amount setting value of the beam table read from the memory 13. By adjusting the phase shift amount and the intensity of the RF signal passing through the reception path R2, the beam pattern of the radio wave received by the phased array antenna module 1 can be changed.

The power detection circuit 70 detects power of the RF signal amplified by the power amplifier 65 and supplied to the antenna element 21, and outputs a signal indicating a detection result as two types of signals including an analog signal and a digital signal. Specifically, a branching device BR in which the RF signal amplified by the power amplifier 65 branches at a stable branch ratio is provided on the transmission path R1 between the power amplifier 65 and the path selection switch 66. One RF signal branching in the branching device BR is supplied to the path selection switch 66, and the other RF signal branching in the branching device BR is supplied to the power detection circuit 70. The power detection circuit 70 detects the power by receiving input of the power of the other RF signal branching in the branching device BR and outputs the signal indicating the detection result as two types of signals including the analog signal and the digital signal.

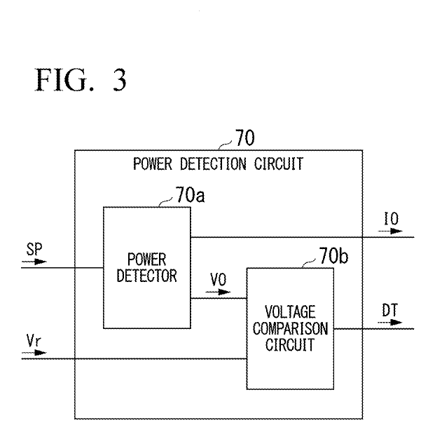

FIG. 3 is a block diagram showing a configuration of the power detection circuit provided in the wireless communication device according to one embodiment of the present invention. As shown in FIG. 3, the power detection circuit 70 includes a power detector 70a and a voltage comparison circuit 70b. The power detector 70a detects the power of the other RF signal SP branching in the branching device BR shown in FIG. 2 and outputs the detection result in two ways of a voltage output VO and a current output IO.

The voltage output VO is a signal (an analog signal) of a voltage that changes in accordance with the detection result of the power of the RF signal SP, and the current output IO is a signal (an analog signal) of a current that changes in accordance with the detection result of the power of the RF signal SP. For example, the voltage output VO may be a signal of a voltage of which a level changes in proportion to magnitude of the detected power, and the current output IO may be a signal of a current of which magnitude changes in proportion to the magnitude of the detected power.

The voltage comparison circuit 70b compares the voltage output VO of the power detector 70a with a predetermined reference voltage Vr and outputs a power detection signal DT corresponding to a comparison result. The power detection signal DT is a digital signal. Specifically, the voltage comparison circuit 70b outputs the power detection signal DT that is at a level "high (H)" (a first level) in a case where the voltage output VO is higher than the reference voltage Vr, and is at a level "low (L)" (a second level) in a case where the voltage output VO is lower than the reference voltage Vr. The reference voltage Vr will be described later.

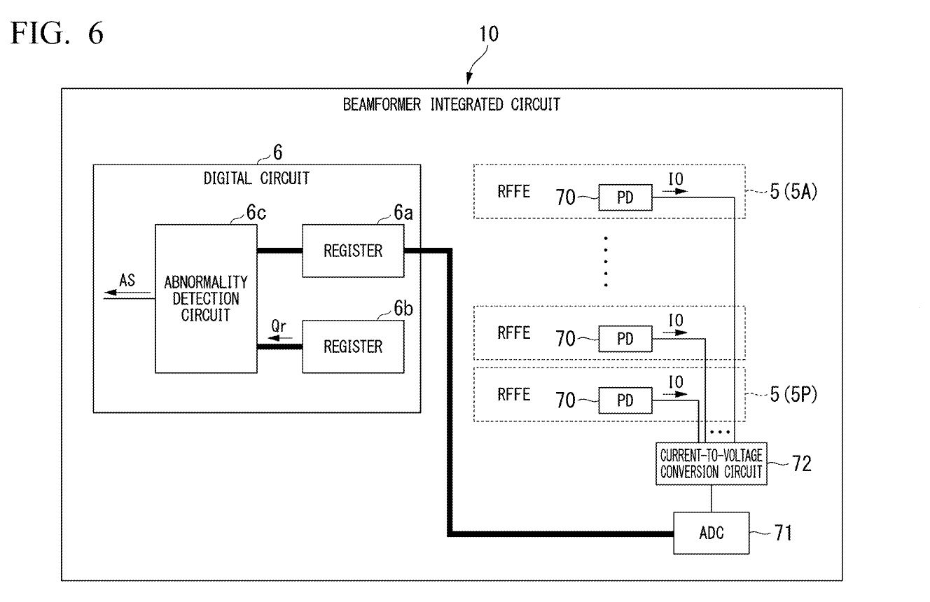

The power detection circuit 70 outputs the current output IO, which is an analog signal, and the power detection signal DT, which is a digital signal. The current output IO which is an analog signal is input into a current-to-voltage conversion circuit 72 (see FIG. 6) provided outside the RF front end 5. The power detection signal DT which is a digital signal is input into the digital circuit portion 11 in the RF front end 5. Two types of signals (the current output IO and the power detection signal DT) are output from the power detection circuit 70 in order to achieve both of early detection of an abnormality in output power of the power amplifier 65 and accurate and precise measurement of the output power.

One ADC 71 is provided for the plurality of RF front ends 5. Thus, the ADC 71 is disposed at a position separated from some of the RF front ends 5 in the beamformer integrated circuit 10. The detection result of the power detector 70a is transmitted to the ADC 71 as the current output IO in order to correctly input the detection result into the ADC 71 even in a case where the ADC 71 is disposed at a position separated from the power detection circuit 70 in the beamformer integrated circuit 10. In a case where the detection result of the power detector 70a is transmitted to the ADC 71 disposed at the separated position as the voltage output VO, it is considered that information deteriorates because of a decrease in voltage occurring on a transmission path, and the detection result is not correctly input into the ADC 71.

The ADC 71 converts one of a plurality of current outputs IO output from a plurality of power detection circuits 70 (more precisely, a voltage converted by the current-to-voltage conversion circuit 72 shown in FIG. 6) into a digital signal. The ADC 71 starts conversion processing in a case where a trigger signal for providing an instruction to start conversion is input. In the ADC 71, a certain number of clocks are required from the start of the conversion processing to completion of the conversion processing. In a case where the conversion processing is completed, the ADC 71 outputs a signal indicating the completion of the conversion. The signal (a digital signal) converted by the ADC 71 can be acquired from the ADC 71 after the above signal indicating the completion of the conversion is output. A frequency of a clock supplied to the ADC 71 is lower than frequencies of clocks supplied to the digital circuit 6 of the beamformer integrated circuit 10 and the digital circuit portion 11 provided in the plurality of RF front ends 5. In a case where the ADC 71 completes the conversion processing, the signal (a digital signal) converted by the ADC 71 may be held in a register.

The digital circuit 6 acquires the digital signal from the ADC 71 in a case where a request to acquire the digital signal converted by the ADC 71 is provided from the controller 50. The digital circuit 6 transmits the acquired digital signal to the controller 50. The digital signal can only be acquired from the ADC 71 after the signal indicating the completion of the conversion into the digital signal is output from the ADC 71.

Each beamformer integrated circuit 10 may be provided with one ADC 71 or may be provided with a plurality of ADCs 71. For example, a configuration in which each beamformer integrated circuit 10 is provided with two ADCs 71 may be adopted. In this configuration, for example, eight power detection circuits provided in the RF front ends 5A to 5H may be connected to the first ADC 71, and eight power detection circuits provided in the RF front ends 5I to 5P may be connected to the second ADC 71.

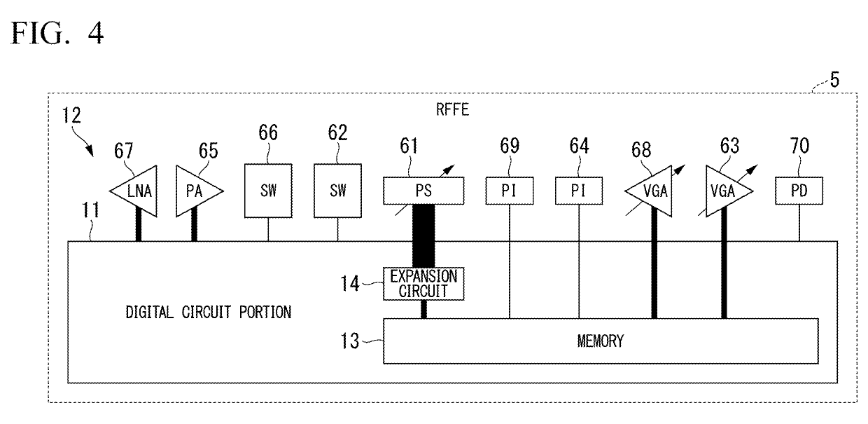

FIG. 4 is a diagram showing a connection relationship between the digital circuit portion and the analog circuit portion provided in the RF front end of the beamformer integrated circuit according to one embodiment of the present invention. As shown in FIG. 4, the phase shifter 61, the variable gain amplifiers 63 and 68, and the phase inverters 64 and 69 provided in the analog circuit portion 12 are controlled in accordance with content of the beam table stored in the memory 13.

Meanwhile, the path selection switches 62 and 66, the power amplifier 65, and the low-noise amplifier 67 provided in the analog circuit portion 12 are controlled by a logic circuit (not shown) such as a register provided in the digital circuit portion 11. The power detection signal DT output from the power detection circuit 70 is input into the digital circuit portion 11.

An expansion circuit 14 expands a bit string of the phase shift amount setting value of the beam table read from the memory 13 into a bit string of a control value (a phase shifter control value) for controlling the phase shifter 61. The phase shift amount setting value stored in the beam table is, for example, 7 bits. The intensity setting value is, for example, 5 bits. The expansion circuit 14 expands a bit string of 6 bits in the phase shift amount setting value of 7 bits to a bit string of the control value of 52 bits. The remaining one bit in the phase shift amount setting value is used to control the phase inverters 64 and 69. The number of bits of the phase shift amount setting value is set in accordance with resolution of the phase shift amount, and the number of bits of the control value is set in accordance with the number of division units constituting the phase shifter 61.

In a case where the most significant bit of the phase shift amount setting value is "1", an instruction to invert the phase is provided to the phase inverters 64 and 69. This corresponds to setting of a phase shift amount of 180 degrees. The lower 6 bits of the phase shift amount setting value are used to provide an instruction for a division unit of which a state is to be changed, among 52 division units constituting the phase shifter 61. When a value of the lower 6 bits of the phase shift amount setting value is "0", all of the 52 division units constituting the phase shifter 61 are in a reference state. When the value is "1" to "52", the division units corresponding to the value among the 52 division units are set to a phase shift state. In a case where the value of the lower 6 bits of the phase shift amount setting value is "52", all of the 52 division units constituting the phase shifter 61 are set to the phase shift state. That is, in a case where the phase shifter 61 is configured with 52 division units, the phase shift state of the phase shifter 61 can be set in 53 levels.

The phase shifter 61 is designed such that the phase shift amount in a case where all of the 52 division units are set to the phase shift state exceeds 180 degrees in a frequency range used in the phased array antenna module 1. In the present embodiment, a configuration in which the phase shift amount of the RF signal passing through the transmission path R1 or the reception path R2 is adjusted by a combination of the phase inverters 64 and 69 and the phase shifter 61 capable of setting the phase shift amount exceeding 180 degrees is described as an example. However, the present invention is not limited to this configuration. A configuration may be adopted in which the phase inverters 64 and 69 are not used and only a phase shifter capable of setting the phase shift amount exceeding 360 degrees is used.

As described above, the lower 6 bits of the phase shift amount setting value are expanded to the bit string (52 bits) of the control value (the phase shifter control value) for controlling the phase shifter 61 by the expansion circuit 14 shown in FIG. 4. That is, the lower 6 bits of the phase shift amount setting value are expanded to a bit string having the same number of bits as the number of division units constituting the phase shifter 61. The number of division units constituting the phase shifter 61 is not limited to 52 and may be any number.

The 5 bits of the intensity setting value correspond to a gain setting value defining gain setting of the variable gain amplifiers 63 and 68. By individually setting the intensity setting value of 5 bits in the variable gain amplifiers 63 and 68, the signal intensity of the RF signal passing through the transmission path R1 and the signal strength of the RF signal passing through the reception path R2 are individually adjusted.

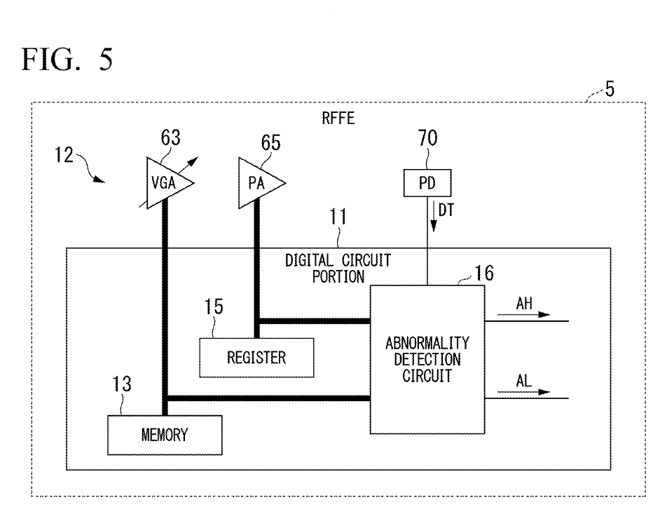

FIG. 5 is a diagram showing a configuration of a first abnormality detection system that detects an abnormality in the output power using the power detection signal output from the power detection circuit according to one embodiment of the present invention. As shown in FIG. 5, the first abnormality detection system includes the memory 13, a register 15, and an abnormality detection circuit 16 (a first abnormality detection circuit) provided in the digital circuit portion 11.

As described above, the memory 13 stores the beam table including the gain setting value defining the gain setting of the variable gain amplifier 63. The register 15 holds a gain setting value defining the gain setting of the power amplifier 65. A gain setting of the analog circuit portion 12 (a gain setting of the circuit portion) for the RF signal passing through the transmission path R1 is defined by the gain setting value read from the memory 13 and the gain setting value held in the register 15. Hereinafter, the gain setting value defining the gain of the analog circuit portion 12 for the RF signal passing through the transmission path R1 will be referred to as a "transmission signal gain setting value".

The abnormality detection circuit 16 detects the presence or absence of an abnormality in the RF signal amplified by the power amplifier 65 and supplied to the antenna element 21, based on the gain setting value read from the memory 13 and the gain setting value held in the register 15, and on the power detection signal DT output from the power detection circuit 70. That is, the abnormality detection circuit 16 detects the presence or absence of an abnormality in the output power of the power amplifier 65 based on the transmission signal gain setting value and on the power detection signal DT output from the power detection circuit 70.

In detecting the presence or absence of an abnormality in the output power of the power amplifier 65, the abnormality detection circuit 16 uses a high output setting reference value RH (a first setting reference value) and a low output setting reference value RL (a second setting reference value). The high output setting reference value RH and the low output setting reference value RL are reference values set for the transmission signal gain setting value.

The high output setting reference value RH is a reference value for determining whether or not the transmission signal gain setting value sets the output power of the power amplifier 65 to be higher than predetermined first power (to a high output). The low output setting reference value RL is a reference value for determining whether or not the transmission signal gain setting value sets the output power of the power amplifier 65 to predetermined second power (to a low output) lower than the first power. The high output setting reference value RH and the low output setting reference value RL are held in a register (not shown) and can be changed based on an instruction from the controller 50.

The high output setting reference value RH and the low output setting reference value RL are set such that the high output setting reference value RH is higher than the low output setting reference value RL in a range in which the output power of the power amplifier 65 may change. In this case, the reference voltage Vr used in the voltage comparison circuit 70b of the power detection circuit 70 is set such that the level of the power detection signal DT is switched when the gain setting value is between the high output setting reference value RH and the low output setting reference value RL.

The abnormality detection circuit 16 outputs a low output abnormality detection signal AL (a first abnormality signal) in a case where the transmission signal gain setting value is higher than the high output setting reference value RH and the power detection signal DT is at the level "L". That is, regardless of the fact that the transmission signal gain setting value is a value for providing an instruction for the high output, the low output abnormality detection signal AL at the level "H" is output in a case where the power detected by the power detection circuit 70 is low.

The abnormality detection circuit 16 outputs a high output abnormality detection signal AH (a second abnormality signal) in a case where the transmission signal gain setting value is lower than the low output setting reference value RL and the power detection signal DT is at the level "H". That is, regardless of the fact that the transmission signal gain setting value is a value for providing an instruction for the low output, the high output abnormality detection signal AH at the level "H" is output in a case where the power detected by the power detection circuit 70 is high.

In a case where the transmission signal gain setting value is lower than the high output setting reference value RH and is higher than the low output setting reference value RL, the abnormality detection circuit 16 does not output the low output abnormality detection signal AL and the high output abnormality detection signal AH regardless of the level of the power detection signal DT. That is, since the transmission signal gain setting value is a value between the value for providing the instruction for the high output and the value for providing the instruction for the low output, detection of an abnormality in the output power is not performed, and the low output abnormality detection signal AL and the high output abnormality detection signal AH are at the level "L".

The abnormality detection circuit 16 can detect an abnormality in the output power with a flexible determination reference corresponding to the content of the beam table (the gain setting value defining the gain setting of the variable gain amplifier 63) and content of the register 15 (the gain setting value defining the gain setting of the power amplifier 65).

In addition, since detection of an abnormality in the output power uses the power detection signal DT which is a digital signal output from the power detection circuit 70, an abnormality in the output power can be detected with high real-time performance.

The high output abnormality detection signal AH and the low output abnormality detection signal AL output from the abnormality detection circuit 16 are acquired by the controller 50. The high output abnormality detection signal AH and the low output abnormality detection signal AL output from the abnormality detection circuit 16 may be stored in the register (not shown) provided in the digital circuit portion 11. The controller 50 may acquire the high output abnormality detection signal AH and the low output abnormality detection signal AL stored in the register by providing an acquisition request to the digital circuit portion 11.

FIG. 6 is a diagram showing a configuration of a second abnormality detection system that detects an abnormality in the output power using the current output supplied from the power detection circuit according to one embodiment of the present invention. As shown in FIG. 6, the second abnormality detection system includes the ADC 71, the current-to-voltage conversion circuit 72, and a register 6a (a storage portion), a register 6b, and an abnormality detection circuit 6c (a second abnormality detection circuit) provided in the digital circuit 6.

The current-to-voltage conversion circuit 72 converts one of the plurality of current outputs IO output from the plurality of power detection circuits 70 into a voltage. Since the current output IO is an analog signal, the voltage converted by the current-to-voltage conversion circuit 72 is also an analog signal. The current-to-voltage conversion circuit 72 is disposed close to the ADC 71. By doing so, the voltage converted by the current-to-voltage conversion circuit 72 is input into the ADC 71 as it is (without changing the voltage as much as possible).

The following configuration is considered as means for selecting one of the plurality of current outputs IO output from the plurality of power detection circuits 70 and inputting the selected current output IO into the current-to-voltage conversion circuit 72. For example, a configuration in which one current output IO is selected by activating only the power detector 70a of one power detection circuit 70 among the plurality of power detection circuits 70 connected to the current-to-voltage conversion circuit 72 and deactivating the power detectors 70a of the remaining power detection circuits 70 is considered. Alternatively, a configuration in which the current output IO output from the plurality of power detection circuits 70 connected to the current-to-voltage conversion circuit 72 through a switch including a plurality of input ports and one output port is selected by controlling the switch is considered.

The register 6a provided in the digital circuit 6 temporarily holds a digital value converted by the ADC 71. The register 6b provided in the digital circuit 6 holds a comparative reference value Qr used for detecting an abnormality in the output power using the current output IO output from the power detection circuit 70. The comparative reference value Qr held in the register 6b can be changed based on an instruction from the controller 50.

The abnormality detection circuit 6c provided in the digital circuit 6 detects the presence or absence of an abnormality in the RF signal amplified by the power amplifier 65 and supplied to the antenna element 21, based on the digital value held in the register 6a and on the comparative reference value Qr held in the register 6b. In a case where the abnormality detection circuit 6c detects an abnormality in the RF signal amplified by the power ampifier 65 and supplied to the antenna element 21, the abnormality detection circuit 6c outputs an abnormality detection signal AS.

The comparative reference value Qr can be set to any value for the digital value converted by the ADC 71. For example, in the case of detecting a high output abnormality in the output power of the power amplifier 65, the comparative reference value Qr is set to a value higher than a value Q11 of the digital signal converted by the ADC 71 when the transmission signal gain setting value is the maximum value. Alternatively, in the case of detecting a low output abnormality in the output power of the power amp 65, the comparative reference value Qr is set to a value lower than a value Q22 of the digital signal converted by the ADC 71 when the transmission signal gain setting value is the minimum value.

The comparative reference value Qr can be set to a value between the above values Q11 and value Q22. In a case where such a value is set, the abnormality detection signal AS output from the abnormality detection circuit 6c is used for a purpose other than a purpose of detecting an output abnormality in the output power of the power amplifier 65. For example, the digital signal output from the ADC 71 accurately indicates the output power of the power amplifier 65 and thus, can be used for a purpose of verifying how accurately the output power of the power amplifier 65 is output with respect to the transmission signal gain setting value.

The abnormality detection circuit 6c compares a precise measurement result obtained by the ADC 71 with any comparative reference value Qr. Accordingly, the presence or absence of an abnormality in the RF signal amplified by the power amplifier 65 and supplied to the antenna element 21 can be accurately detected.

The abnormality detection signal AS output from the abnormality detection circuit 6c is acquired by the controller 50. The abnormality detection signal AS output from the abnormality detection circuit 6c may be stored in a register (not shown) provided in the digital circuit 6. The controller 50 may acquire the abnormality detection signal AS stored in the register by providing an acquisition request to the digital circuit 6.

As described above, in the present embodiment, the detection result of the output power of the power amplifier 65 is output in two ways of the voltage output VO and the current output IO. The voltage output VO corresponding to one of the ways is compared with the predetermined reference voltage Vr, and the power detection signal DT which is a digital signal of which a signal level changes in accordance with the comparison result is output. The power detection circuit 70 according to the present embodiment outputs the power detection signal DT indicating the comparison result between the voltage output VO and the reference voltage Vr and the current output IO indicating the detection result of the output power of the power amplifier 65. Accordingly, both of early detection of an abnormality in the output power of the power amplifier 65 and accurate and precise measurement of the output power can be achieved.

While the power detection circuit, the radio frequency integrated circuit, and the wireless communication device according to the embodiment of the present invention have been described above, the present invention is not limited to the above embodiment and can be freely modified within the scope of the present invention. For example, while the power detection signal DT described above is a signal that is at the level "H" in a case where the voltage output VO is higher than the reference voltage Vr and is at the level "low (L)" in a case where the voltage output VO is lower than the reference voltage Vr, the signal levels may be reversed.

The same applies to other digital signals.

The phased array antenna module described in the above embodiment is used for a time-division multiplexing system. However, the phased array antenna module of the present invention may be used for a frequency-division multiplexing system.

In addition, in the above-described embodiment, an example has been described in which one antenna element 21 is connected to one RF front end 5 on a one-to-one basis. However, in the present invention, two front ends may be connected to a dual polarization antenna element including a connection terminal for the horizontal polarization and a connection terminal for the vertical polarization.

What is claimed is:

1. A power detection circuit comprising:
a power detector configured to detect output power of a power amplifier and output in two ways of a voltage output and a current output as a detection result; and
a voltage comparison circuit configured to compare the voltage output of the power detector with a predetermined reference voltage and output a power detection signal that is at a first level when the voltage output is higher than the reference voltage and is at a second level when the voltage output is lower than the reference voltage.

2. A radio frequency integrated circuit comprising:
the power detection circuit according to claim 1 configured to detect the output power of the power amplifier;
a circuit portion that includes the power amplifier and a variable gain amplifier and is configured to amplify a radio frequency signal supplied to an antenna element; and
a first abnormality detection circuit configured to detect presence or absence of an abnormality in the radio frequency signal based on a gain setting value defining a gain of the circuit portion and on the power detection signal output from the voltage comparison circuit of the power detection circuit.

3. The radio frequency integrated circuit according to claim 2,
wherein the first abnormality detection circuit
outputs a first abnormality signal in a case where the gain setting value is higher than a first setting reference value and the power detection signal is at the second level, and
outputs a second abnormality signal in a case where the gain setting value is lower than a second setting reference value lower than the first setting reference value and the power detection signal is at the first level.

4. The radio frequency integrated circuit according to claim 3,
wherein the first abnormality detection circuit does not output the first abnormality signal and the second abnormality signal in a case where the gain setting value is lower than the first setting reference value and higher than the second setting reference value.

5. The radio frequency integrated circuit according to claim 3,
wherein the reference voltage is set such that a level of the power detection signal is switched when the gain setting value is a value between the first setting reference value and the second setting reference value.

6. A radio frequency integrated circuit comprising:
a circuit portion including a power amplifier that amplifies a radio frequency signal supplied to an antenna element;
the power detection circuit according to claim 1 configured to detect the output power of the power amplifier;
a conversion circuit configured to convert the current output of the power detector into a digital value; and
a second abnormality detection circuit configured to detect presence or absence of an abnormality in the radio frequency signal based on the digital value and a predetermined comparative reference value.

7. The radio frequency integrated circuit according to claim 6,
wherein the comparative reference value is set to a value higher than the digital value converted by the conversion circuit when a gain setting value defining a gain setting of the circuit portion is a maximum value, or a value lower than the digital value converted by the conversion circuit when the gain setting value is a minimum value.

8. The radio frequency integrated circuit according to claim 6, further comprising:
a storage portion configured to store the digital value converted by the conversion circuit,
wherein the second abnormality detection circuit detects the presence or absence of the abnormality in the radio frequency signal based on the digital value stored in the storage portion and the comparative reference value.

9. A wireless communication device comprising:
the radio frequency integrated circuit according to claim 2; and
a controller configured to acquire a detection result of the first abnormality detection circuit.

10. A wireless communication device comprising:
the radio frequency integrated circuit according claim 6, and
a controller configured to acquire a detection result of the second abnormality detection circuit.

11. A wireless communication device comprising:
the radio frequency integrated circuit according to claim 3, and
a controller configured to acquire a detection result of the first abnormality detection circuit.

12. A wireless communication device comprising:
the radio frequency integrated circuit according to claim 4; and
a controller configured to acquire a detection result of the first abnormality detection circuit.

13. A wireless communication device comprising:
the radio frequency integrated circuit according to claim 5; and
a controller configured to acquire a detection result of the first abnormality detection circuit.

14. A wireless communication device comprising:
the radio frequency integrated circuit according claim 7, and
a controller configured to acquire a detection result of the second abnormality detection circuit.

15. A wireless communication device comprising:
the radio frequency integrated circuit according claim 8, and
a controller configured to acquire a detection result of the second abnormality detection circuit.
